(19) United States
(12) Patent Application Publication
(10) Pub. No.: US 2002/0181624 A1
(43) Pub. Date: Dec. 5, 2002

(54) Method and apparatus for making a channel estimate

(76) Inventors: Juan G. Gonzalez, Morris, NJ (US); Salim Manji, Middlesex, NJ (US)

Correspondence Address: HARNESS, DICKEY & PIERCE, P.L.C., P.O. BOX 8910, RESTON, VA, 20195, US

(21) Appl. No.: 09/837,387

(22) Filed: Apr. 19, 2001

(51) Int. Cl. H03K 5/01

(52) U.S. Cl. 375/346

(57) ABSTRACT

In the method of making a channel estimate, at least first and second confidence levels that a transmitted data symbol has respective first and second values are determined based on a received data symbol corresponding to the transmitted data symbol. A channel estimate is then determined based on the first and second confidence levels.

### BACKGROUND OF THE INVENTION

1. Field of the Invention

The present invention relates to channel estimation in a telecommunication system, and more particularly, data-aided channel estimation.

2. Description of Related Art

It is very well known that coherent methods of channel estimation give about 3 dB of gain over non-coherent methods, provided that perfect knowledge of the channel fading parameters (amplitude and phase) is known. In practical applications, such perfect knowledge is never achieved, and a receiver must estimate the fading parameters. This estimation is prone to errors, and thus, the “promised” 3 dB gain may rapidly start to vanish as the accuracy of the channel-estimation algorithm decreases. This problem appears in communication systems where channel fading and coherent detection are present (e.g., CDMA2000, 3GPP, and ARIB—where the channel parameters are usually estimated from a pilot signal). Common losses from channel estimation errors in these systems can range from 0.1 dB up to 3 dB, depending on the specifics of the channel and the system.

Under consideration is the problem of estimating the complex-valued channel gain (also called “complex fading coefficient”) experienced by a BPSK-modulated symbol transmitted over a single path of a (possibly multipath) fading channel. A complex discrete-time received sequence is generated by demodulation (e.g., correlator or matched filter) and sampling of each path. For symbol i, the effect of fading on the received signal, yᵢ, can be modeled as

yᵢ=aᵢxᵢ+vᵢ

where a, is the complex-valued fading coefficient, x, ∈{±1} is the transmitted data bit (which can be either +1 or −1), and vᵢ, is the complex background additive white Gaussian noise with zero mean and per-component variance σ². It is assumed that the fading is sufficiently slow so that the channel gain is approximately constant over consecutive symbols. Hence, the symbol subscript on the channel gain a is removed.

Conventional DS-CDMA channel estimation is performed through the use of a reference signal known as a pilot. The pilot may be transmitted in a number of different ways. One approach is to provide a channel, separate from the data channel, exclusively for the pilot signal. This method is used by both the European (UMTS) and the North American (CDMA 2000) third generation wireless systems. A second approach is to time-multiplex pilot symbols with data symbols. This approach is used, for example, in the Japanese third generation wireless system (ARIB). Although the above two methods have fundamental differences, the underlying concept is the same.

With pilot-aided (PA) channel estimation, the pilot data bit, χᵢ, is known to the receiver. Without loss of generality, we assume that χᵢ=1 for all pilot symbols. Therefore, for pilot symbol i, the received signal statistic y_{i,p} is

y_{i,p}=aₚ+vᵢ

where aₚ is the complex channel gain for the pilot signal, vᵢ represents the background noise and is Gaussian, and p represents that a variable is based on pilot symbols. Typically, the transmit energy of the pilot signal is kept as small as possible in an effort to minimize the consumption of battery power and added interference. Hence, the pilot signal does not necessarily have the same energy as the data signal. Since the goal is to estimate a and not aₚ, the following weighting is applied to the channel gain of the pilot signal

y_{i,p}=βa+vᵢ

where β is a known, chosen design parameter.

For each received pilot symbol, a simple individual estimated realization of the channel gain, â_{i,p}, can be formulated as

â_{i,p}=y_{i,p}

Data-aided (DA) channel estimation offers an alternative approach by making use of the data symbols in addition to (or in lieu of) the pilot symbols. The difficulty with DA estimation is that the data symbols are not known a priori (as is the case with pilot symbols), which makes the estimation more challenging—and more noisy too. DA channel estimation can be implemented in conjunction with PA channel estimation by means of a stage-by-stage iterative procedure. In the first stage, a PA-only channel estimate is generated. This estimate is then used to detect the data symbols, which in turn are used as new “pseudo-pilot” information to revise the PA channel estimate. This process can be repeated, and may be implemented as a loop within the decoding stage of the receiver. Typically, the information in each data symbol is estimated, then the information is removed and a channel gain estimate is generated using an averaging window.

DA channel estimation is an efficient way to assist channel estimation because it makes use of data information that is already available at the receiver. The goal is to reduce the pilot symbol overhead and/or reduce the required transmit energy of pilot symbols. However, conventional DA channel estimate methods are computationally intensive and exhibit larger than desired variance.

### SUMMARY OF THE INVENTION

In the method of the present invention, estimated individual realizations of the complex-valued fading coefficient, commonly called channel estimates, are generated. According to the inventive method, these realizations are easy to generate and can produce a channel estimate that exhibits a smaller variance in comparison to conventional methods.

A level of confidence for each possible value of a transmitted data symbol is determined based on a received data symbol corresponding to the transmitted data symbol. The confidence level associated with a particular possible value is the level of confidence that the transmitted symbol was the particular possible value. Using the confidence levels, a channel estimate is generated.

Unlike conventional data-aided channel estimate methods, the method according to the present invention does not require making an explicit calculation (called a hard decision) of an estimate of the transmitted symbol. Instead the present invention offers a soft decision alternative that does not require performing any maximizations. Consequently, the methodology of the present invention offers an easy means of determining a data-aided channel estimate that exhibits a smaller variance in comparison to conventional methods.

### BRIEF DESCRIPTION OF THE DRAWINGS

The present invention will become more fully understood from the detailed description given herein below and the accompanying drawings which are given by way of illustration only, wherein like reference numerals designate corresponding parts in the various drawings, and wherein:

FIG. 1 illustrates a plot of the confidence function h(y_{i,d}) versus the log-likelihood ratio λ; and

FIG. 2 illustrates an apparatus for making a channel estimate according to one embodiment of the present invention.

### DETAILED DESCRIPTION OF THE PREFERRED EMBODIMENTS

In the method of the present invention, estimated individual realizations of the complex-valued fading coefficient, commonly called channel estimates, are generated. According to the inventive method, these realizations are easy to generate and can produce a channel estimate that exhibits a smaller variance in comparison to conventional methods.

Using the received signal y_{i,d}, the channel estimate is defined as:

â_{i,d}=h(y_{i,d})y_{i,d}. (1)

where â_{i,d} is the channel estimate, h( ) is any predefined function that can be designed based on a specific constellation and channel being used, i represents the ith estimate, and d represents that the parameter or variable pertains to data symbols (as opposed to a pilot symbols).

For the purposes of discussion only, the method of the present invention will described for the bi-phase shift keying (BPSK) constellation and an over-the-air communication channel. In BPSK, the transmitted symbol is either +1 or −1. However, from the following disclosure, it will be understood that application of the method of the present invention is not limited to a particular constellation or channel. In a preferred embodiment for BPSK modulation, h(y_{i,d}) is defined as:

h(y_{i,d})=P(xᵢ=+1|y_{i,d})−P(xᵢ=−1|y_{i,d}), (2)

where P(xᵢ=+1|y_{i,d}) is the a posteriori probability that a transmitted data symbol xᵢ=+1 was transmitted conditioned on the observation of the received data symbol y_{i,d} corresponding to the transmitted data symbol xᵢ, and where P(xᵢ=−1|y_{i,d}) is the a posteriori probability that a transmitted data symbol xᵢ=−1 was transmitted conditioned on the observation of the received data symbol y_{i,d} corresponding to the transmitted data symbol xᵢ. Here, P(xᵢ=+1|y_{i,d}) represents a confidence level, based on the received data symbol y_{i,d}, that the corresponding transmitted data symbol xᵢ had a value of +1. And, P(xᵢ=−1|y_{i,d}) represents a confidence level, based on the received data symbol y_{i,d}, that the corresponding transmitted data symbol xᵢ had a value of −1.

Using Bayes' rule, equation (2) can be rewritten as equation (3a) below:

$$P ( {x}_{i} = + 1 \vert {y}_{i , d} ) = \frac{p ( {y}_{i , d} \vert {x}_{i} = + 1 ) P ( {x}_{i} = + 1 )}{p ( {y}_{i , d} )} \qquad \text{(3a)}$$

where p(y_{i,d}) represents a probability density function of the received statistic evaluated at y_{i,d}.

A similar expression exists for P(xᵢ=−1|y_{i,d}).

$$P ( {x}_{i} = - 1 \vert {y}_{i , d} ) = \frac{p ( {y}_{i , d} \vert {x}_{i} = - 1 ) P ( {x}_{i} = - 1 )}{p ( {y}_{i , d} )} \qquad \text{(3b)}$$

Under the assumption that P(xᵢ=+1)=P(xᵢ=−1)=0.5 using the Law of Total Probability, p(y_{i,d}) is given by equation (4) below:

$$p ( {y}_{i , d} ) = \frac{1}{2} ( p ( {y}_{i , d} \vert {x}_{i} = + 1 ) + p ( {y}_{i , d} \vert {x}_{i} = - 1 ) ) \qquad \text{(4)}$$

The well-known log-likelihood ratio (LLR) is defined as:

$$λ ( y ) = {λ}_{1} ( y ) - {λ}_{- 1} ( y ) = ln ( \frac{p ( y \vert x = + 1 )}{p ( y \vert x = - 1 )} ) \qquad \text{(5)}$$

where In( ) represents the natural logarithm. It is known that y conditioned on x is a complex Gaussian random variable with mean ax and per-components variance σ², (i.e., noise), where σ² is determined according to any well-known technique. Therefore, the LLR is given by equation (6) below:

$$λ ( y ) = {λ}_{1} ( y ) - {λ}_{- 1} ( y ) = - ( \frac{{( y - a )}^{2}}{2 {σ}^{2}} ) - ( \frac{{( y + a )}^{2}}{2 {σ}^{2}} ) = \frac{2 {a}^{*} y}{{σ}^{2}} \qquad ( 6 )$$

Combining Equations (1)-(6) results in:

$${\hat{a}}_{i , d} = ( \frac{{e}^{{λ}^{( {y}_{i , d} )}} - 1}{{e}^{{λ}^{( {y}_{i , d} )}} + 1} ) {y}_{i , d} . \qquad ( 7 )$$

Returning to Equation (2), h (y_{i,d}) is given by:

$$h ( {y}_{i , d} ) = \frac{{e}^{{λ}^{( {y}_{i , d} )}} - 1}{{e}^{{λ}^{( {y}_{i , d} )}} + 1} . \qquad ( 8 )$$

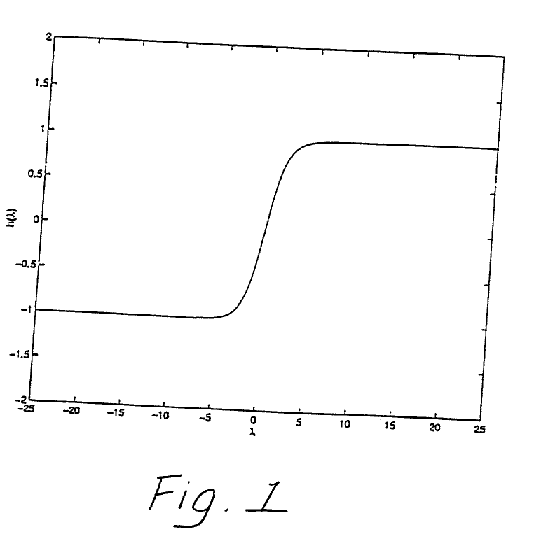

A plot of this function with respect to λ is given in FIG. 1. The function is odd and is bounded by ±1, and bears a strong resemblance to the sign( ) function.

As will be appreciated, h(y_{i,d}) represents the confidence that the transmitted symbol xᵢ is a particular value in view of the corresponding received symbol y_{i,d}. Stated another way, h(y_{i,d}) indicates the strength or degree of confidence that the transmitted symbol xᵢ is a particular value in view of the corresponding received symbol y_{i,d}.

Next, the overall data-based estimate is found by averaging the individual realizations of the channel estimate over a weighted time window:

$${\hat{a}}_{d} = \frac{1}{2 {N}_{d} + 1} {\sum }_{j = i - {N}_{d}}^{i + {N}_{d}} {K}_{j , d} {\hat{a}}_{j , d} = \frac{1}{2 {N}_{d} + 1} {\sum }_{j = i - {N}_{d}}^{i + {N}_{d}} {K}_{j , d} ( \frac{{e}^{λ ( {y}_{i , d} )} - 1}{{e}^{λ ( {y}_{i , d} )} + 1} ) {y}_{i , d} \qquad ( 9 )$$

where K_{i,d} is a weighting constant, 2N_{d}+1 is the window over which the estimate is averaged, and N_{d} is a number of samples.

Unlike conventional data-aided channel estimate methods, the method according to the present invention does not require making an explicit calculation (called a hard decision) of an estimate of the transmitted symbol. Instead the present invention offers a soft decision alternative that does not require performing any maximizations. A simple evaluation of the LLR, a well-known receiver calculation already made in most receivers, is used. Consequently, the methodology of the present invention offers an easy means of determining a data- aided channel estimate that exhibits a smaller variance in comparison to conventional methods.

Once the appropriate pilot-aided (PA) and data-aided (DA) channel estimates and their variances are obtained, they can be combined in an optimal manner. In the present invention, optimality is defined as minimum variance in the final estimate. The PA channel estimate â^{(p)} can be determined according to any well-known technique, and therefore will not be described. The variances σₚ² and σ_{d}² of the PA and DA channel estimates â^{(p)} and â^{(d)} can be determined according to any well-known statistical technique; and therefore will not be described. The final channel estimate, â is a linear combination of the PA and DA channel estimates,

$$\hat{a} = {w}_{p} {\hat{a}}^{( p )} + {w}_{d} {\hat{a}}^{( d )} , \qquad \text{(10)}$$

where wₚand w_{d} are non-negative constants. Assuming that E[â^{(p)}]=E[â^{(d)}]=a, where E[] represents the average value, the added constraint that

wₚ+w_{d}=1 (11)

ensures that E[â]=a.

Under the assumption that the PA and DA channel estimates are independent, the variance of the overall estimate is

Var(â)+wₚ²σₚ²+w_{d}²σ_{d}². (12)

To minimize this variance subject to the constraint in equation (11) and wₚ,w_{d} being non-negative, w_{d}=1−wₚ is substituted in Equation (12). Then, equation (12) is differentiated with respect to wₚ, set equal to zero, and solved for wₚ. The result is

$$\begin{matrix}{w}_{p} = \frac{{σ}_{d}^{2}}{{σ}_{p}^{2} + {σ}_{d}^{2}} , \\ and & ( 13 ) \\ {w}_{d} = \frac{{σ}_{d}^{2}}{{σ}_{p}^{2} + {σ}_{d}^{2}} & \text{(14)}\end{matrix}$$

A check of the second derivative confirms that the solution is indeed a minimum.

Accordingly, by substituting equations (13) and (14) into equation (10), the channel estimate can be calculated using the PA channel estimate, the variance of the PA channel estimate, the DA channel estimate and the variance of the DA channel estimate.

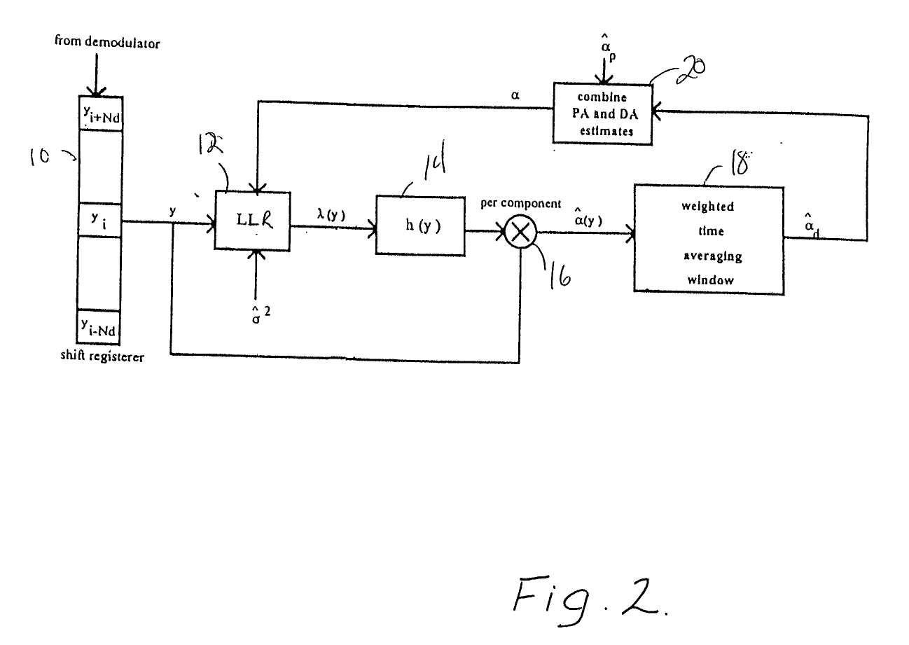

An apparatus for implementing the above-described embodiment of the present invention will now be described with reference to FIG. 2. As will be appreciated from the forgoing, the apparatus of FIG. 2 forms a part of a receiver. Because the other components of the receiver are well-known, applicants have not illustrated and will not describe these other components for the sake of brevity.

As shown in FIG. 2, a shift register 10 inputs the received symbols yᵢ from a demodulator (not shown). As alluded to above, also not shown are the well-known components for determining the per-component noise or variance σ², the pilot-aided channel estimate âₚ, the variance σₚ² of the pilot-aided channel estimate and the variance σ_{d}² of the data aided channel estimate. An LLR calculator 12 receives the received symbol yᵢ from the shift register 10 and the square of the standard deviation, and calculates the LLR of the received symbol yᵢ according to equation (6). As will be appreciated, equation (6) requires, during a first iteration, an initial channel estimate as an input variable. In a preferred embodiment, the channel estimate based on the pilot symbols is used as the initial channel estimate, and then each subsequent iteration uses the channel estimate determined based on the combined data aided and pilot-aided channel estimates as shown in FIG. 2.

Next, a confidence factor generator 14 generates a confidence factor h(y) according to equation (8) using the output of the LLR calculator 12. A multiplier 16 multiplies the confidence factor with the received symbol yᵢ on a per component basis to obtain an individual realization of the channel estimate based on the received data according to equation (1). A weighted time window averager 18 stores the output of the multiplier 16 and calculates a weighted average of the data-aided channel estimate according to equation (9).

A channel estimate combiner 20 receives the output of the weighted time window averager 18 and the pilot symbol based channel estimate, calculates the variances of the DA channel estimate and the PA channel estimate, and generates the channel estimate according to equations (10), (13) and (14). The channel estimate is then used in the conventional manner to determine the transmitted symbols xᵢ, and is also feedback to the LLR calculator 12 to be used in the LLR calculation.

The invention being thus described, it will be obvious that the same may be varied in many ways. Such variations are not to be regarded as a departure from the spirit and scope of the invention, and all such modifications are intended to be included within the scope of the following claims.

We claim:

1. A method of making a channel estimate, comprising:
determining at least first and second confidence levels that a transmitted data symbol has respective first and second values based on a received data symbol corresponding to the transmitted data symbol; and
generating a channel estimate based on the first and second confidence levels.

2. The method of claim 1, wherein the first confidence level represents a first probability that the transmitted data symbol is the first value and the second confidence level represents a second probability that the transmitted data symbol is the second value.

3. The method of claim 1, wherein the generating step generates the channel estimate based on the first and second confidence levels and the received data symbol.

4. The method of claim 1, further comprising:
generating an overall channel estimate by obtaining a weighted average of a plurality of channel estimates generated by said generating a channel estimate step over a time window of predetermined width.

5. A method of making a channel estimate, comprising:
generating a confidence factor according to a confidence function and a received data symbol, the confidence factor representing a confidence level that a transmitted data symbol corresponding to the received data symbol has a particular symbol value; and
generating a channel estimate based on the confidence factor and the received data symbol.

6. The method of claim 5, wherein the confidence function includes generating a log-likelihood ratio on the received data symbol.

7. The method of claim 5, wherein the generating a confidence factor step generates the confidence factor according to the confidence function, the received data symbol and a variance of the channel estimate.

8. The method of claim 5, further comprising:
generating an overall channel estimate by obtaining a weighted average of a plurality of channel estimates generated by said generating a channel estimate step over a time window of predetermined width.

9. A method of making a channel estimate, comprising:
determining a strength indicator based on a received data symbol corresponding to a transmitted data symbol, a value of the strength indicator indicating a likelihood that the transmitted data symbol is a particular value; and
generating a channel estimate based on the confidence factor and the received data symbol.

10. The method of claim 9, wherein in a bi-phase shift keying communication system, the strength indicator approaches a value of 1 the greater the likelihood that the transmitted data symbol was 1 and approaches a value of −1 the greater the likelihood that the transmitted data symbol was −1.

11. The method of claim 9, wherein the determining step determines, for each possible symbol value, a probability that the transmitted data symbol is the possible symbol value based on the received data symbol, and determines the strength indicator from the determined probabilities.

12. The method of claim 11, wherein the determining step performs the probability determinations and the strength indicator determination according to a predetermined function.

13. The method of claim 9, further comprising:
generating an overall channel estimate by obtaining a weighted average of a plurality of channel estimates generated by said generating a channel estimate step over a time window of predetermined width.
